(19) United States
(12) Patent Application Publication
(10) Pub. No.: US 2009/0017606 A1
(43) Pub. Date: Jan. 15, 2009

(54) Method for Producing a Semiconductor Component Having Regions Which are Doped to Different Extents

(75) Inventors: Peter Fath, Konstanz (DE); Ihor Melnyk, Konstanz (DE)

Correspondence Address: LERNER GREENBERG STEMER LLP, P O BOX 2480, HOLLYWOOD, FL, 33022-2480, US

(73) Assignee: GP SOLAR GMBH, Konstanz (DE)

(21) Appl. No.: 12/178,087

(22) Filed: Jul. 23, 2008

Related U.S. Application Data
(63) Continuation of application No. PCT/EP2007/000463, filed on Jan. 19, 2007.

(30) Foreign Application Priority Data
Jan. 23, 2006 (DE) 10 2006 003 283.7

(51) Int. Cl. H01L 21/22

(52) U.S. Cl. 438/558; 257/E21.135

(57) ABSTRACT

A method for producing a semiconductor component, in particular a solar cell, having regions which are doped to different extents. A layer is formed which inhibits the diffusion of a dopant and can be penetrated by a dopant, on at least one part of the surface of a semiconductor component material. The diffusion-inhibiting layer is at least partially removed in at least one high-doping region. A dopant source is formed on the diffusion-inhibiting layer and in the at least one high-doping region. Then the dopant is diffused from the dopant source into the semiconductor component material. The semiconductor component is suitable for use in integrated circuits, electronic circuits, solar cell modules, and to produce solar cells having a selective emitter structure.

### CROSS-REFERENCE TO RELATED APPLICATION

This is a continuation application, under 35 U.S.C. § 120, of copending international application No. PCT/EP2007/000463, filed Jan. 19, 2007, which designated the United States; this application also claims the priority, under 35 U.S.C. § 119, of German patent application No. DE 10 2006 003 283.7, filed Jan. 23, 2006; the prior applications are herewith incorporated by reference in their entirety.

### BACKGROUND OF THE INVENTION

### Field of the Invention

The invention relates to a method for producing a semiconductor component, in particular a solar cell, having regions that are doped to different extents. The invention also pertains to the integration of such semiconductor components in integrated circuits, electronic circuits, and solar cell modules and to produce solar cells having a selective emitter structure.

When producing a large number of semiconductor components, it is necessary to provide regions which are doped to different extents. Semiconductor components in the sense of this description are understood as meaning not only commercially used electronic components but also semi-finished products and doped semi-conductor structures. That is to say, in the extreme case, even a semiconductor which has only regions which are doped differently.

For example, when producing solar cells, regions which are doped to different extents are provided in order to form an emitter structure in this manner. The emitter structure is based on heavy doping in certain regions and on light doping in the other regions. This so-called selective emitter structure, in which metal contacts are usually formed in the highly doped regions, is known to make it possible to dissipate current efficiently with simultaneously little charge carrier recombination in the other lightly doped regions.

### SUMMARY OF THE INVENTION

It is accordingly an object of the invention to provide a method of producing a semiconductor component which overcomes the above-mentioned disadvantages of the heretofore-known devices and methods of this general type and which provides for a simple and low-complexity method for producing a semiconductor component having regions which are doped to different extents.

With the foregoing and other objects in view there is provided, in accordance with the invention, a method of producing a semiconductor component with regions that are doped to different extents, the method which comprises:

forming a diffusion-inhibiting layer on at least one part of a surface of a semiconductor component material, the diffusion-inhibiting layer being a porous layer configured to inhibit a diffusion of a dopant and being permeable to the dopant;

at least partially removing the diffusion-inhibiting layer in at least one high-doping region;

forming a dopant source on the diffusion-inhibiting layer and in the at least one high-doping region; and

diffusing the dopant from the dopant source into the semiconductor component material.

The basic concept of the invention is to form a layer, which inhibits the diffusion of a dopant and can be penetrated by a dopant, on at least one part of the surface of a semiconductor component material. Said layer is then at least partially removed in at least one region to be highly doped (i.e., a high-doping region). A dopant source is then formed on the diffusion-inhibiting layer and in the at least one high-doping region. Dopant is finally diffused from this dopant source into the semiconductor component material. According to this aspect of the invention, the diffusion-inhibiting layer is in the form of a porous layer.

During the diffusion, dopant passes in a comparatively unimpeded manner from that part of the dopant source which is formed in the at least one high-doping region into the semiconductor component material since the diffusion-inhibiting layer has been at least partially removed there. After a certain diffusion duration, a relatively large amount of dopant has passed into the semiconductor component material at these locations. The desired high level of doping is therefore present in the high-doping regions.

In contrast, in those regions in which the part of the surface of the semiconductor component material is under the diffusion-inhibiting layer, only a small amount of dopant passes into the semiconductor component material. Consequently, the latter is lightly doped in these regions. In this case, the sheet resistance in regions of the part of the surface of the semiconductor component material which are under the diffusion-inhibiting layer which has not been removed may be determined, inter alia, by the thickness of the diffusion-inhibiting layer.

This makes it possible to produce semiconductor components having regions which are doped to different extents in a simple manner and with little complexity, in particular without the need for masking steps, in which parts of the diffused regions of the semiconductor component material are protected from being etched away by means of a material which is inert to the etching medium, and without having to carry out a plurality of diffusion operations.

A semiconductor component which has been produced in this manner can be used, according to the invention, in integrated circuits or electronic circuits.

In addition, the invention includes using the method according to the invention to produce solar cells which constitute semiconductor components and have a selective emitter structure.

Moreover, the invention provides for at least one solar cell produced in accordance with the method according to the invention to be used to produce solar cell modules.

In principle, any semiconductor material, in particular silicon or gallium or compounds thereof, may be used as the semiconductor component material. It goes without saying that the use of compound semiconductors is also conceivable.

In most applications, the semiconductor component material has basic doping. For example, p-doped or n-doped silicon may thus be used. Known dopants such as phosphorus or boron may be used for this purpose. The dopants to be introduced and the relevant dopant sources should be matched to the basic doping prevailing in the semiconductor component material taking into account the method of operation of the semiconductor component. For example, when producing a solar cell having a selective emitter structure, an n-type dopant, for example phosphorus, should thus be selected in the case of a p-doped solar cell material.

One development of the method according to the invention provides for the diffusion-inhibiting layer to be formed by spinning-on and subsequent drying, chemical vapor deposition (CVD) or thermal growth in furnace processes. In this case, such thermal growth in a furnace process may be carried out, for example, in a furnace of the type of a diffusion furnace known from semiconductor technology. In this case, a substance or a mixture of substances is passed through a tube of the heated furnace, if necessary with the aid of a carrier gas, said substance or mixture interacting with semiconductor component material arranged in the tube in such a manner that the diffusion-inhibiting layer is accumulated or deposited or the like on the semiconductor component material.

Another configuration variant of the invention provides for the diffusion-inhibiting layer to be completely removed in the at least one high-doping region. This makes it possible to introduce a particularly large amount of dopant at this location. However, depending on the semiconductor component and the steps also needed to produce it, complete removal of the diffusion-inhibiting layer may also be disadvantageous. For example, during mechanical removal or removal using a laser, the so-called ablation laser, damage to the crystal surface may arise, which damage results in increased charge carrier recombination at these locations. This may in turn impair the function of semiconductor components, for example solar cells. Against this background, it may appear to be expedient to only partially remove the diffusion-inhibiting layer in the at least one high-doping region and to leave a remnant. Although this remnant may impede diffusion, said diffusion is nevertheless considerably greater in the high-doping regions than in the remaining regions covered by a full-thickness diffusion-inhibiting layer, if the layer thicknesses and diffusion times are designed appropriately.

Suitable technologies, for example an ablation laser with a sufficiently high input of energy, make it possible to remove the diffusion-inhibiting layer in high-doping regions, if appropriate even without damaging the crystal surface. In these cases, it is possible to dispense with leaving a remaining, thin diffusion-inhibiting layer in the high-doping regions.

One exemplary embodiment of the invention provides for the semiconductor component to be in the form of a solar cell, at least some metal contacts, preferably finger contacts, being arranged in the highly doped regions. In this case, finger contacts should be understood as meaning slender contacts which are used to collect the generated current while the active solar cell surface is simultaneously shaded to the least possible extent.

Other features which are considered as characteristic for the invention are set forth in the appended claims.

Although the invention is illustrated and described herein as embodied in method for producing a semiconductor component having regions which are doped to different extents, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE SEVERAL VIEWS OF THE DRAWING

FIG. 1 is a diagrammatic illustration of a first exemplary embodiment of the method according to the invention;

FIG. 2A is a diagrammatic illustration of a first portion of a method for producing a solar cell having a selective emitter structure as a second exemplary embodiment of the method according to the invention; and

FIG. 2B shows the continuation of the method sequence from FIG. 2A.

### DETAILED DESCRIPTION OF THE INVENTION

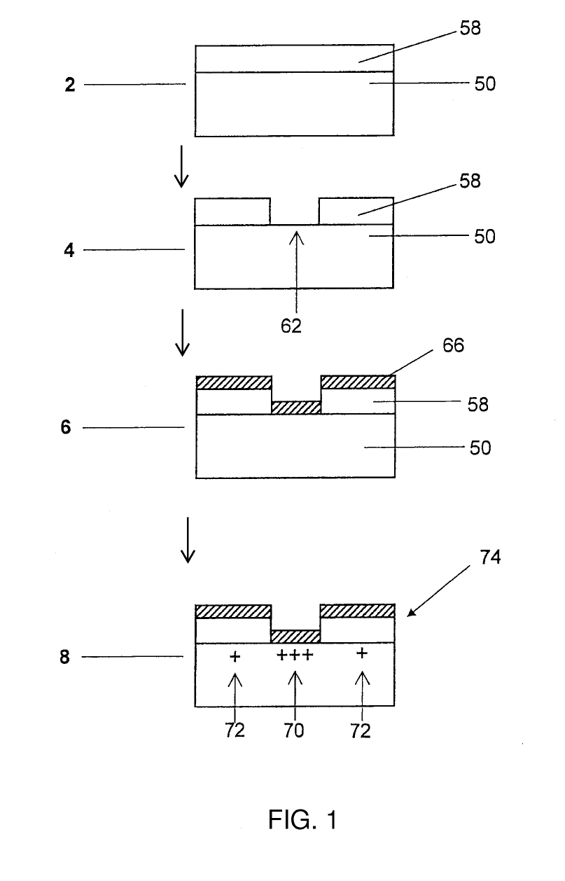

Referring now to the figures of the drawing in detail and first, particularly, to FIG. 1 thereof, there is shown, diagrammatically, a first exemplary embodiment of the method according to the invention. A diffusion-inhibiting layer 58 which can be penetrated by a dopant is first of all formed (2) on a top-side surface 56 of a semiconductor component material 50. The diffusion-inhibiting layer 58 is then completely removed (4) in at least one high-doping region 62, i.e., in one region that is to be highly doped.

This is followed by the formation (6) of a dopant source 66 from which a dopant diffuses under certain conditions. In this case, the dopant source 66 is applied to the diffusion-inhibiting layer 58 as well as in the high-doping region 62. In the latter case, it comes to lie directly on the top-side surface 56 of the semiconductor component material 50 on account of the complete removal of the diffusion-inhibiting layer 58 in this region. The dopant source 66 may be, for example, a phosphorus glass. However, any other dopant source is also conceivable in principle.

Dopant then diffuses (8) from the dopant source 66 out of and into the top-side surface 56 of the semiconductor component material 50. This is effected in most cases by the supply of thermal energy. In the case of those regions of the top-side surface 56 of the semiconductor component material 50 which are covered by the diffusion-inhibiting layer 58, dopant moves through the diffusion-inhibiting layer in this case, as a result of which only a certain proportion of the dopant released in the dopant source 66 can pass into the semiconductor component material.

In contrast, in the high-doping region 62, the dopant passes unimpeded into the top-side surface 56 of the semiconductor component material. Consequently, there is heavy doping 70 in the area surrounding the high-doping region 62 in the top-side surface 56 of the semiconductor component material, whereas weak doping 72 results in those regions of the top-side surface 56 which are under the diffusion-inhibiting layer 58.

This easily produces a semiconductor component having regions which are doped to different extents.

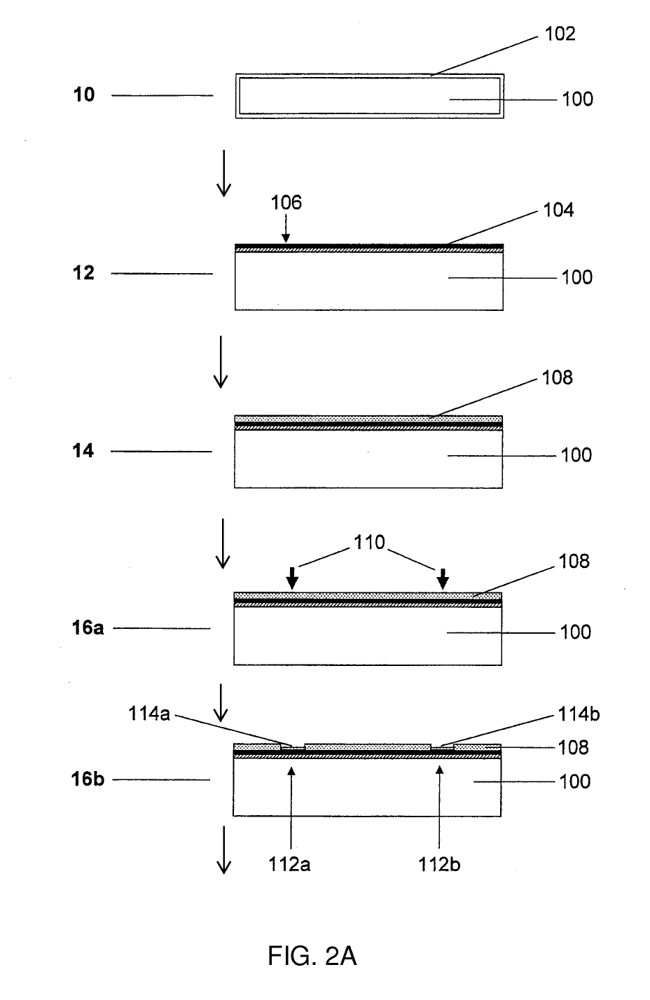

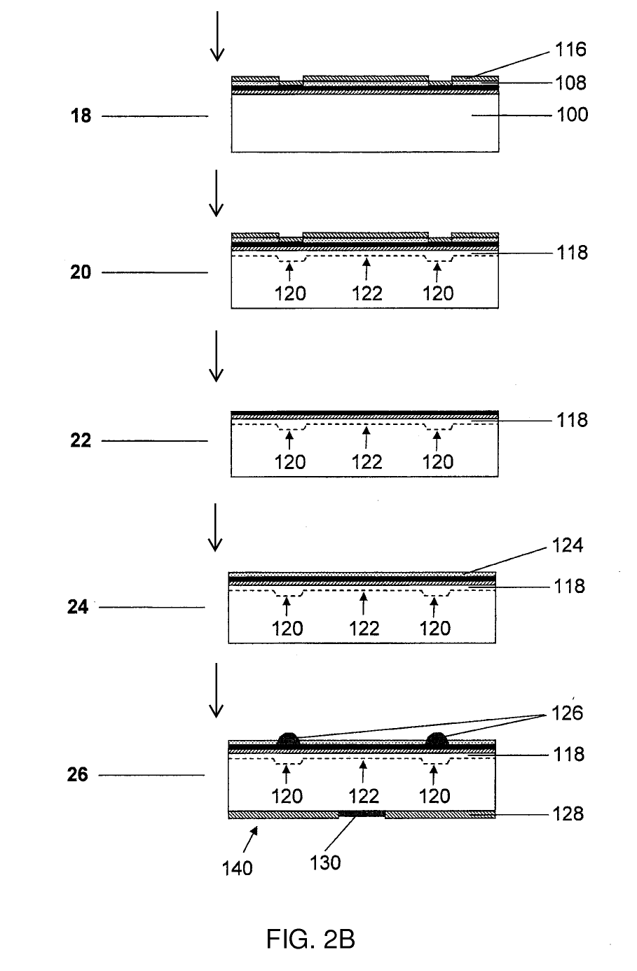

FIGS. 2A and 2B show a method sequence for producing a solar cell having a selective emitter structure, i.e., another exemplary embodiment of the method according to the invention. The starting point of the method is formed by the provision (10) of the starting solar cell material, which, in the present exemplary embodiment, is formed by p-doped solar cell material, in particular silicon. In an analogous manner, n-doped solar cell material could also form the starting point. The dopants used and the dopant source would then have to be selected such that they are matched in a corresponding manner.

In the diagrammatically illustrated case in FIG. 2A, the solar cell material 100 has sawing damage 102, as usually occurs in the case of semiconductor wafers which have been severed from a molded block or a pulled ingot by means of sawing. This sawing damage is first of all removed (12), which is usually effected by overetching the silicon wafer or the solar cell material 100, and a texture 104 is made (12) in the top-side surface 106 of the solar cell material 100. In this case, the texture 104 may be realized using known methods such as chemical or mechanical texturing.

The diffusion-inhibiting layer is then formed (14) in the form of a porous layer 108 of solar cell material 100. In the case that the solar cell material is silicon, this may be effected, for example, using an etching solution which contains hydrofluoric acid (HF), nitric acid (HNO₃), and water (H₂O), preferably in a mixing ratio of HF:HNO₃:H₂O in the range of from 100:1-2:5-10. In this case, the porous layer 108 is formed in a thickness of less than 200 nm, preferably in a thickness in the range of from 80 to 120 nm.

After this, ablation laser light 110 is applied (16a) in high-doping regions 112a, 112b. With this input of energy, the porous layer 108 evaporates in the high-doping regions, but the layer is only partially removed (16b), however, in the present exemplary embodiment. As a result, a remnant 114a, 114b of the porous layer 108 remains. This precludes the surface of the solar cell material 100 from being damaged and the charge carrier recombination from being increased in the high-doping regions 112a, 112b.

A dopant source is then formed (18). Since the solar cell material is p-doped material, phosphorus is used in the present case as the most common n-type dopant. However, other dopants may also be used. In this exemplary embodiment, the dopant source is in the form of phosphorus glass 116. This may be effected, for example, in a furnace process in which the solar cell material is exposed to a stream of POCI₃, if necessary supplemented with a carrier gas. In addition, phosphorus may also be provided in a dopant source in another manner, for example by spinning on and subsequently drying a phosphorus-containing paste or solution or by chemical or physical deposition of phosphorus-containing compounds.

The phosphorus then diffuses (20) from the phosphorus glass, or if appropriate other dopant sources, into the solar cell material. In this case, the diffusion from the phosphorus glass 116 into the top-side surface 106 of the solar cell material 100 is inhibited by the porous layer of solar cell material 108. Since porous silicon material is still also present in the high-doping regions 112a, 112b in this exemplary embodiment, diffusion is also inhibited here, but to a considerably lesser extent than in those regions in which the porous layer 108 is still present in its entire thickness. Since only a small remnant 114a, 114b of the porous layer 108 is present in the high-doping regions 112a, 112b, considerably more dopant may thus pass into the top-side surface 106 of the solar cell material in these regions in the same amount of time. Consequently, low-impedance emitter regions 120 are formed here. For the rest, high-impedance emitter regions 122 are formed. Overall, the result is an emitter structure 118 having high-impedance regions 122 and low-impedance regions 120, which is usually referred to as a selective emitter.

After diffusion (20), the porous layer 108 and the phosphorus glass 116 acting as the dopant source have fulfilled their purpose and are removed together. This is preferably carried out in a joint etching step (22).

An antireflection coating 124 is then applied (24). Metal contacts 126, 128, 130 are then formed (26) on the front side of the solar cell 140 and on the rear side of the latter. In the present exemplary embodiment, the metal contacts 126 of the front side are arranged in this case in the low-impedance regions 120 of the emitter structure 118. This makes it possible to ensure a low contact resistance between the emitter structure 118 and the metal contacts 126, whereas there is little charge carrier recombination in the other regions on account of the high-impedance emitter regions 122. Typical sheet resistance values Rs are approximately 10 to 30 Ω/square (ohms per square) for low-impedance emitter regions 120 and approximately 80 to 140 Ω/square for high-impedance emitter regions 122.

In order to improve the conversion efficiency, a back-surface field which is known per se and, in the present case, is composed of a flat aluminum rear-side metallization is applied to the rear side. The back-surface field is penetrated by at least one local rear-side metal contact 130 which contact-connects the p-doped solar cell material 100.

The method according to the invention can obviously also be applied to solar cell concepts other than that described in conjunction with FIGS. 2A and 2B. In particular, it may be used with bifacial cells, in which both the front side and the rear side of the solar cell are used to generate current, and with solar cells which are contact-connected completely on the rear side.

1. A method of producing a semiconductor component with regions that are doped to different extents, the method which comprises:
forming a diffusion-inhibiting layer on at least one part of a surface of a semiconductor component material, the diffusion-inhibiting layer being a porous layer configured to inhibit a diffusion of a dopant and being permeable to the dopant;
at least partially removing the diffusion-inhibiting layer in at least one high-doping region;
forming a dopant source on the diffusion-inhibiting layer and in the at least one high-doping region; and
diffusing the dopant from the dopant source into the semiconductor component material.

2. The method according to claim 1, which comprises forming the porous diffusion-inhibiting layer from semiconductor component material.

3. The method according to claim 1, which comprises forming the porous diffusion-inhibiting layer in a thickness of less than 200 nm.

4. The method according to claim 1, which comprises forming the porous diffusion-inhibiting layer in a thickness between 80 nm and 120 nm.

5. The method according to claim 2, which comprises, in order to form the porous layer from the semiconductor component material, exposing at least a part of the surface of the semiconductor component to an etching solution.

6. The method according to claim 5, wherein the etching solution contains hydrofluoric acid, nitric acid, and water.

7. The method according to claim 5, wherein the etching solution contains hydrofluoric acid, nitric acid, and water in a mixing ratio of HF:HNO₃:H₂O of 100:1 to 2:5 to 10.

8. The method according to claim 2, which comprises, in order to form the porous layer from the semiconductor component material, exposing at least a part of the surface of the semiconductor component to an etching plasma.

9. The method according to claim 1, which comprises at least partially removing the diffusion-inhibiting layer in the high-doping region using ablation laser light.

10. The method according to claim 9, which comprises removing the diffusion-inhibiting layer with light from a frequency-doubled or frequency-tripled ablation laser.

11. The method according to claim 1, which comprises at least partially removing the diffusion-inhibiting layer in the at least one high-doping region with an etching paste.

12. The method according to claim 11, wherein the etching paste contains hydrofluoric acid.

13. The method according to claim 11, which comprises applying the etching paste to the at least one high-doping region with a printing or injection-molding process.

14. The method according to claim 13, which comprises applying the etching paste with a printing process selected from the group consisting of screen-printing, stamp-printing, spray-printing, and web-printing.

15. The method according to claim 1, which comprises, after the dopant has diffused from the dopant source into the part of the surface of the semiconductor component material, removing the dopant source together with the diffusion-inhibiting layer.

16. The method according to claim 1, wherein the semiconductor component is configured as a solar cell with at least some metal contacts disposed in high-doping regions thereof.

17. The method according to claim 16, wherein the solar cell has high-doping regions formed on a front side and on a rear side thereof.

18. The method according to claim 16, which comprises forming the dopant source from phosphorus glass and forming the diffusion-inhibiting layer from porous solar cell material, and removing the phosphorus glass together with the layer of porous solar cell material by etching in an etching solution or a plasma.

19. The method according to claim 16, wherein the high-doping regions are broader than a metallization subsequently applied at the high-doping regions.

20. The method according to claim 16, which comprises forming a solar cell having a selective emitter structure.
